(19) United States
(12) Patent Application Publication
(10) Pub. No.: US 2024/0120254 A1
(43) Pub. Date: Apr. 11, 2024

(54) THERMALLY-CONDUCTIVE SHEET AND ELECTRONIC DEVICE

(71) Applicant: DEXERIALS CORPORATION, Shimotsuke-shi, Tochigi (JP)

(72) Inventors: Keisuke ARAMAKI, Shimotsuke-shi, Tochigi (JP); Yuma SATO, Shimotsuke-shi, Tochigi (JP); Yusuke KUBO, Shimotsuke-shi, Tochigi (JP)

(73) Assignee: DEXERIALS CORPORATION, Shimotsuke-shi, Tochigi (JP)

(21) Appl. No.: 18/276,509

(22) PCT Filed: Feb. 9, 2022
(86) PCT No.: PCT/JP2022/005029

§ 371 Date: Aug. 9, 2023

(30) Foreign Application Priority Data
Feb. 18, 2021 (JP) 2021-023935

(51) Int. Cl. H01L 23/373; H01L 23/00; H01L 23/367

(52) U.S. Cl. CPC H01L 23/3737; H01L 23/3672; H01L 24/32; H01L 2224/29291; H01L 2224/29318; H01L 2224/29324; H01L 2224/29386; H01L 2224/29393; H01L 2224/29399; H01L 2224/32245; H01L 2924/05032; H01L 2924/05432

(57) ABSTRACT

A thermally-conductive sheet includes: a binder; and an anisotropic thermally-conductive filler. The anisotropic thermally-conductive filler is oriented in a thickness direction of the thermally-conductive sheet An arithmetical mean height Sa is 5 μm or less and a maximum height Sz is 50 μm or less on either surface of the thermally-conductive sheet. A dielectric breakdown voltage of the thermally-conductive sheet is 0.5 kV/mm or higher.

### TECHNICAL FIELD

The present invention relates to a thermally-conductive sheet and electronic device.

### BACKGROUND ART

As electronic devices become even more sophisticated, semiconductor devices are becoming denser and have more objects implemented therein. Thus, it has become important to more efficiently dissipate heat generated from electronic components that configure the electronic device. To efficiently dissipate heat, semiconductors are attached to a heat sink such as a heat dissipation fan and heat dissipation plates through a thermally-conductive sheet. Silicone containing dispersed fillers such as inorganic fillers are widely used as thermally-conductive sheets. In such heat-dissipating members, further improvement of thermal conductivity is required, and this is generally managed by increasing the filler content of inorganic fillers mixed in the matrix to achieve high thermal conductivity.

However, increasing the filler content of inorganic filler has limitations because when the filler content of inorganic filler is increased with respect to a thermally-conductive sheet, the flexibility of the thermally-conductive sheet is compromised and powdering occurs due to the high filler content of inorganic filler. Inorganic fillers include, for example, alumina, aluminum nitride, and aluminum hydroxide. Moreover, scale-like particles such as boron nitride and graphite, and carbon fibers or the like may be filled into the matrix to achieve high thermal conductivity of the thermally-conductive sheet. This is due to the anisotropy of thermal conductivity possessed by the scale-like particles or the like.

For example, carbon fiber has a thermal conductivity of approximately 600 to 1200 W/mK in the direction of the fibers. In the case of boron nitride, it is known to be anisotropic and have a thermal conductivity of approximately 110 W/mK in the face direction and approximately 2 W/mK in the direction perpendicular to the face direction. In this manner, carbon fibers and the face direction of scale-like particles is the same as the direction of heat transfer, which is the thickness direction of the sheet. That is, by orienting carbon fibers and scale-like particles in the thickness direction of the sheet, thermal conductivity can be dramatically improved.

### CITATION LIST

### Patent Documents

Patent Document 1: Japanese Patent No. 6650175
Patent Document 2: Japanese Patent Application Publication No. 2012-23335
Patent Document 3: Japanese Patent No. 6082777

### SUMMARY OF INVENTION

### Problem to be Solved by Invention

Insulating thermally-conductive sheets are manufactured by filling ceramic fillers such as alumina, but the low thermal conductivity of thermally-conductive fillers makes it impossible to obtain a thermally-conductive sheet having low thermal resistance. Boron nitride is an example of a ceramic filler having high thermal conductivity. Because the shape of boron nitride is scale-like, it must be oriented in the thickness direction to obtain high thermal conductivity.

Therefore, boron nitride can be oriented in the thickness direction of a thermally-conductive sheet by making a molded block from the resin composition for forming the thermally conductive sheet and slicing the molded block. However, favorable thermal resistance may not be obtained simply by slicing the molded block in this manner to create a thermally-conductive sheet. Moreover, the thermal conductivity of insulating fillers is inferior to that of conductive fillers.

In light of the above, an object of the present invention is to provide a thermally-conductive sheet capable of favorably transferring heat in the thickness direction, and an electronic device.

### Means for Solving Problem

In order to solve the problems described above and achieve the object, the thermally-conductive sheet according to the present invention is a thermally conductive sheet containing a binder and an anisotropic thermally-conductive filler, wherein the anisotropic thermally-conductive filler is oriented in the thickness direction, Sa is 5 μm or less on either side of the thermally-conductive sheet, Sz is 50 μm or less, and the dielectric breakdown voltage is 0.5 kV/mm or higher.

### Effects of Invention

According to the present invention, it is possible to obtain a thermally-conductive sheet having low thermal resistance while still having insulating properties.

### BRIEF DESCRIPTION OF DRAWINGS

FIG. 1 is a diagram illustrating one example of a thermal conduction sheet in which the present art is applied.

FIG. 2 is a perspective drawing illustrating one example of a step for slicing a thermally-conductive molded body.

FIG. 3 is a diagram illustrating one example of a semiconductor device.

### DESCRIPTION OF THE EMBODIMENTS

Embodiments of the present invention will be described below in detail with reference to attached drawings. The present invention is not limited by the embodiments described below. Furthermore, in the descriptions in the drawings, identical or corresponding elements are appropriately marked with the same reference numerals. Additionally, it should be noted that the drawings are schematic and the relationship of the dimensions of each element and the like may differ from the actual object. The drawings may also contain parts that differ from other drawings in dimensional relationships and proportions.

(Configuration Example of Thermally-Conductive Sheet)

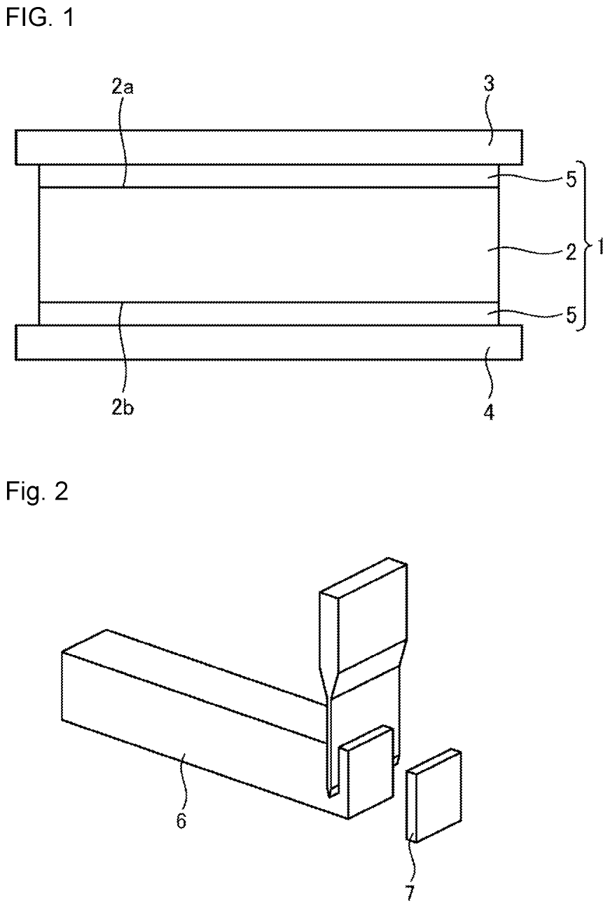

FIG. 1 is a diagram illustrating one example of a thermally-conductive sheet in which the present art is applied. A thermally-conductive sheet 1 illustrated in FIG. 1 has a sheet body 2 and a resin coating layer 5. The sheet body 2 is a cured binder resin including at least a polymer matrix component and a fibrous thermally-conductive filler. The resin coating layer 5 is formed by an uncured polymer matrix component that exudes from the sheet body 2. A first release film 3 is attached on one side 2a of the sheet body 2, and a second release film 4 is attached on another side 2b of the sheet body 2.

The thermally-conductive sheet 1 has tack (adhesiveness) due to the resin coating layer 5 being formed on the one side 2a and the other side 2b, and the sheet body 2 can be adhered to a predetermined position by peeling off the first release film 3 and the second release film 4 when used. This makes the thermally-conductive sheet 1 easy to work with and handle. Furthermore, the thermally-conductive sheet 1 has excellent reworkability for correcting misalignment when assembling electronic components and heat-dissipating members, enabling disassembly and reassembly for some reason after assembly, and the like.

(Polymer Matrix Component)

The polymer matrix component that configures the sheet body 2 is the polymer component that serves as the base material for the thermally-conductive sheet 1. The type thereof is not particularly limited, and known polymer matrix components can be appropriately selected. One example of a polymer matrix component is a thermosetting polymer.

The above thermosetting polymers include, for example, cross-linked rubbers, epoxy resins, polyimide resins, bismaleimide resins, benzocyclobutene resins, phenolic resins, unsaturated polyesters, diallyl phthalate resins, silicone resins, polyurethane, polyimide silicone, thermosetting polyphenylene ether, thermosetting modified polyphenylene ether, and the like. These may be used alone or in combination of two or more of the above.

Note that cross-linked rubbers include, for example, natural rubber, butadiene rubber, isoprene rubber, nitrile rubber, hydrogenated nitrile rubber, chloroprene rubber, ethylene propylene rubber, chlorinated polyethylene, chlorosulfonated polyethylene, butyl rubber, halogenated butyl rubber, fluororubber, urethane rubber, acrylic rubber, polyisobutylene rubber, silicone rubber, and the like. These may be used alone or in combination of two or more of the above.

Furthermore, among these thermosetting polymers, it is preferable to use silicone resin for its excellent moldability and weather resistance, as well as its adhesiveness and trackability to electronic components. The silicone resin described above is not particularly limited, and the type of silicone resin can be appropriately selected depending on the object thereof.

In terms of obtaining moldability, weather resistance, adhesion, and the like described above, it is preferable that the silicone resin is a silicone resin consisting of a liquid silicone gel main agent and a curing agent. Such silicone resins include, for example, addition-reaction type liquid silicone resin, heat vulcanization type millable type silicone resin using peroxide for vulcanization. Among these, addition-reaction type liquid silicone resins are particularly preferable as heat-dissipating members of electronic devices because adhesion between the heat-generating surface of the electronic component and the heat-sink surface is required.

As the addition-reaction type liquid silicone resin described above, it is preferable to use a two-liquid addition-reaction type silicone resin or the like, wherein polyorganosiloxane having a vinyl group is the main agent and polyorganosiloxane having a Si—H group is the curing agent.

Here, the liquid silicone component has a silicone A liquid component that serves as the main agent and a silicone B liquid component that contains a curing agent, and the silicone A liquid component and the silicone B liquid component are blended in a predetermined ratio. Although the mixing ratio of the silicone A liquid component and the silicone B liquid component can be adjusted appropriately, it is preferable that the mixing ratio be such that the sheet body 2 is flexible and the uncured component of the polymer matrix component can be bled between the side 2a and the first release film 3 and between the side 2b and the second release film 4 to form a resin coating layer 5.

Moreover, the content of the polymer matrix component described above in the thermally-conductive sheet 1 is not particularly limited and can be appropriately selected according to the object thereof. However, in terms of ensuring sheet moldability, sheet adhesiveness, and the like, it is preferable for the content thereof to be 15% to 50% by volume, and more preferably 20% to 45% by volume.

(Fibrous Thermally-Conductive Filler)

The fibrous thermally-conductive filler included in the thermally-conductive sheet 1 is a component that improves the thermal conductivity of the sheet. The type of thermally-conductive filler is not particularly limited as long as it is a fibrous material having high thermal conductivity, but it is preferable to use carbon fiber in terms of obtaining higher thermal conductivity.

Note that one type of thermally-conductive filler may be used alone, or a mixture of two or more types may be used. When two or more types of thermally-conductive fillers are used, they may all be fibrous thermally-conductive fillers, or a mixture of a fibrous thermally-conductive filler and another form of thermally-conductive filler may be used. Other forms of thermally-conductive fillers include metals such as silver, copper, and aluminum, ceramics such as alumina, aluminum nitride, silicon carbide, and graphite, and the like.

The type of carbon fiber described above is not particularly limited, and can be appropriately selected depending on the object thereof. For example, pitch-based, PAN-based, graphitized PBO fibers, and those synthesized by arc discharge, laser evaporation, CVD (chemical vapor deposition), and CCVD (catalytic chemical vapor deposition) methods can be used. Among these, carbon fibers having graphitized PBO fibers and pitch-based carbon fibers are further preferable because of their high thermal conductivity.

Furthermore, the carbon fibers described above can be used after undergoing a partial or full surface treatment, if necessary. Such surface treatments include, for example, oxidation, nitriding, nitration, sulfonation, or treatments to attach or bond metals, metal compounds, organic compounds, and the like to the functional groups introduced on the surface by these treatments or to the surface of the carbon fiber. The functional groups described above include, for example, hydroxyl groups, carboxyl groups, carbonyl groups, nitro groups, amino groups, and the like.

Furthermore, at least a portion of the surface of the carbon fibers described above may be coated using an insulating material. Materials used for coating include insulating inorganic materials such as SiO2 and thermosetting or UV-curing resins such as epoxy resin, (meth)acrylic resin, and divinylbenzene. Coating methods include, for example, when the insulating material is inorganic, deposition on the carbon fiber surface by the sol-gel method. For thermosetting resin, coating methods include adding carbon fiber to a solution in which a monomer and a polymerization initiator or curing agent is dissolved, where the polymerization reaction is carried out while stirring to deposit the polymer insoluble in the solvent on the surface of the carbon fiber for coating, and the like. For thermosetting resins, it is preferable to use monomers having two or more functionalities.

Additionally, while the average fiber length (average length on the major axis) of the carbon fiber is not particularly limited and can be selected appropriately, in terms of reliably obtaining high thermal conductivity, it is preferably in a range of 50 μm to 300 μm, more preferably in the range of 75 μm to 275 μm, and particularly preferably in the range of 90 μm to 250 μm.

Additionally, while the average fiber diameter (average length on the minor axis) of the carbon fiber is not particularly limited and can be selected appropriately, in terms of reliably obtaining high thermal conductivity, it is preferably in a range of 4 μm to 20 μm, and more preferably in the range of 5 μm to 14 μm.

In terms of reliably obtaining high thermal conductivity, it is preferable for the aspect ratio (average major axis length/average minor axis length) of the carbon fibers to be 8 or higher, and more preferable to be 9 to 30. When the aspect ratio is less than 8, the thermal conductivity may decrease due to the short fiber length (major axis length) of the carbon fiber. Meanwhile, if the aspect ratio exceeds 30, the dispersibility in the thermally-conductive sheet 1 may decrease, resulting in insufficient thermal conductivity.

Here, the average major axis length and average minor axis length of the carbon fiber can be measured, for example, by microscope, scanning electron microscope (SEM), and the like, and the average can be calculated from multiple samples.

Moreover, the content of the fibrous thermally-conductive filler described above in the thermally-conductive sheet 1 is not particularly limited and can be appropriately selected according to the object thereof. However, it is preferable for the content thereof to be 4% to 40% by volume, and more preferably 5% to 35% by volume. When the content thereof is less than 4% by volume, it may be difficult to obtain sufficiently low thermal resistance, and when the content thereof exceeds 40% by weight, the moldability of the thermally-conductive sheet 1 and the orientation of the fibrous thermally-conductive filler may be affected. Moreover, the content of the thermally-conductive filler described including the fibrous thermally-conductive filler in the thermally-conductive sheet 1 is preferably 15% to 75% by volume.

Note that the fibrous thermally-conductive filler is exposed on the sides 2a and 2b of the sheet body 2 and is in thermal contact with heat sources such as electronic components and heat-dissipating members such as heat sinks. When the fibrous thermally-conductive filler exposed on the sides 2a and 2b of the sheet body 2 is coated using the uncured component of the polymer matrix component, the thermally-conductive sheet 1 can reduce the contact thermal resistance between the fibrous thermally-conductive filler and electronic component and the like when mounted on the electronic component and the like.

(Inorganic Filler)

The thermally-conductive sheet 1 may further contain an inorganic filler as a thermally-conductive filler. By containing an inorganic filler, the thermal conductivity of the thermally-conductive sheet 1 can be enhanced and the strength of the sheet can be improved. The inorganic filler described above is not particularly limited in relation to shape, material, average particle size, or the like, and can be appropriately selected depending on the purpose thereof. The above shapes include, for example, spherical, ellipsoidal, lumpy, granular, flattened, needle-like, and the like. From among these, spherical and elliptical shapes are preferable in terms of filling properties, with a spherical shape being particularly preferable.

Examples of inorganic filler materials include, for example, aluminum nitride (AlN), silica, alumina (aluminum oxide), boron nitride, titania, glass, zinc oxide, silicon carbide, silicon (silicone), silicon oxide, metal particles, and the like. These may be used alone or in combination of two or more of the above. From among these, alumina, boron nitride, aluminum nitride, zinc oxide, and silica are preferable, and alumina and aluminum nitride are particularly preferred in terms of thermal conductivity.

Furthermore, an inorganic filler that has undergone a surface treatment can be used. When such a surface treatment is performed on the inorganic filler using a coupling agent, the dispersibility of the inorganic filler is improved and the flexibility of the thermally-conductive sheet 1 is improved.

The average particle size of the inorganic filler can be appropriately selected depending on the type of inorganic material or the like. When the inorganic filler is alumina, it is preferable for the average particle size therefore to be 1 μm to 10 μm, more preferably 1 μm to 5 μm, and particularly preferably 4 μm to 5 μm. When the average particle size is less than 1 μm, the viscosity may increase, making it difficult to mix. Meanwhile, when the average particle size exceeds 10 μm, the thermal resistance of the thermally-conductive sheet 1 may increase.

Additionally, when the inorganic filler is aluminum nitride, it is preferable for the average particle size therefore to be 0.3 μm to 6.0 μm, more preferably 0.3 μm to 2.0 μm, and particularly preferably 0.5 μm to 1.5 μm. When the average particle size is less than 0.3 μm, the viscosity may increase, making it difficult to mix, and if it exceeds 6.0 μm, the thermal resistance of the thermally-conductive sheet 1 may increase.

Note that the average particle size of the inorganic filler can be measured, for example, using a particle size distribution meter or a scanning electron microscope (SEM).

Note that the inorganic filler described above may be used to replace of the fibrous thermally-conductive filler described above. In this case, a needle or scale shape is preferable, particularly a scale shape, because it is easier to demonstrate thermal conductivity in the thickness direction. Boron nitride is the preferable material for a scale-shaped inorganic filler.

(Other Components)

In addition to the polymer matrix component, fibrous thermally-conductive filler, and inorganic filler included as appropriate, the thermally-conductive sheet 1 can also contain other components as appropriate based on the purpose thereof. Other components include, for example, magnetic powders, thixotropic agents, dispersants, curing accelerators, retarders, slight tackifiers, plasticizers, flame retardants, antioxidants, stabilizers, coloring agents, and the like. The content of magnetic powder may be adjusted to give the thermally-conductive sheet 1 electromagnetic wave absorption performance.

(Magnetic Powder)

The thermally-conductive sheet 1 may adjust the content of magnetic powder to give the thermally-conductive sheet 1 electromagnetic wave absorption performance.

The type of the magnetic powder is not particularly limited so long as it is magnetic, and known magnetic powders can be appropriately selected. For example, amorphous metal powders and crystalline metal powders can be used. Amorphous metal powders include, for example, Fe—Si—B—Cr-based metal powders, Fe—Si—B-based metal powders, Co—Si—B-based metal powders, Co—Zr-based metal powders, Co—Nb-based metal powders, Co—Ta-based metal powders, and the like, and crystalline metal powders include, for example, pure iron, Fe-based crystalline metal powders, Co-based crystalline metal powders, Ni-based crystalline metal powders, Fe—Ni-based crystalline metal powders, Fe Co-based crystalline metal powders, Fe—Al-based crystalline metal powders, Fe—Si-based crystalline metal powders, Fe—Si—Al-based crystalline metal powders, Fe—Ni—Si—Al-based crystalline metal powders, and the like. Additionally, as crystalline metal powders described above, a microcrystalline metal powder may be used in which a small amount of N (nitrogen), C (carbon), O (oxygen), B (boron), and the like are added to the crystalline metal powder to make it finer.

Note that for the magnetic metal powder described above, a mixture of two or more types having different materials or different average particle sizes may be used.

Furthermore, for the magnetic metal powder described above, it is preferable to adjust the shape such as spherical or flat. For example, when enhancing filling properties, it is preferable to use a magnetic metal powder having a particle size of several μm to several tens of μm and that is spherical in shape. Such magnetic metal powders can be produced, for example, by atomization or by pyrolysis of metal carbonyls. Atomization is a method that has the advantage that spherical powders can be easily created, wherein molten metal is discharged through a nozzle, and the discharged molten metal is sprayed with a jet stream of air, water, inert gas, or the like to solidify it as droplets to produce a powder. When amorphous magnetic metal powder is produced using atomization, it is preferable for the cooling rate to be about 1×106 (K/s) to prevent crystallization of the molten metal.

When amorphous alloy powder is produced using atomization described above, the surface of the amorphous alloy powder can be made smooth. As such, the use of amorphous alloy powders having few surface irregularities and a small specific surface area as magnetic metal powders can enhance the filling properties for polymer matrix components. In addition, performing a coupling treatment can further improve filling properties.

(Method for Manufacturing Thermally-Conductive Sheet)

Next, the manufacturing process of the thermally-conductive sheet 1 will be described. The manufacturing process of the thermally-conductive sheet 1 in which this art is applied has a process (process A) for molding a thermally-conductive resin composition containing a fibrous thermally-conductive filler or the like in a polymer matrix component into a predetermined shape and curing to form a thermally-conductive molded body, a process (process B) for slicing the thermally-conductive molded body into a sheet to form a molded body sheet, and a process (process C) for interposing the molded body sheet between the first release film 3 and the second release film 4 and pressing to make the surface of the molded body sheet smoother and to form the resin coating layer 5. Note that here, a description is given wherein a fibrous thermally-conductive filler is used, but the same manufacturing process can be used when using a scale-shaped inorganic filler instead of a fibrous thermally-conductive filler, and appropriate changes can be made in the following process.

(Process A)

In process A, the polymer matrix component, fibrous thermally-conductive filler, inorganic filler included as appropriate, and other components described above are mixed to prepare a thermally-conductive resin composition. Note that the procedure for mixing and preparing each component is not particularly limited, for example, a thermally-conductive resin composition is prepared by adding a fibrous thermally-conductive filler, as appropriate, an inorganic filler, magnetic powder, and other components to the polymer matrix component, and mixing.

Next, a fibrous thermally-conductive filler such as carbon fiber is oriented in one direction. The method of orientation of the filler is not particularly limited as long as it is means that can orient in one direction. For example, by extruding or press fitting the thermally-conductive resin composition under high shear force into a hollow mold, it is relatively easy to orient the fibrous thermally-conductive filler in one direction, and the orientations of the fibrous thermally-conductive fillers are the same (within ±10°).

A specific example of the method of extruding or press-fitting the thermally-conductive resin composition under high shear force into a hollow mold described above includes an extrusion molding method or a mold molding method. When the thermally-conductive resin composition is extruded from the die in the extrusion molding method, or when the thermally-conductive resin composition is press fit into the die in the mold molding method, the thermally-conductive resin composition flows and the fibrous thermally-conductive filler is oriented along the flow direction. When doing so, the fibrous thermally-conductive filler is more easily oriented if a slit is installed at the tip of the die.

The thermally-conductive resin composition extruded or press-fitted into a hollow mold is molded into a block shape according to the shape and size of the mold, and a thermally-conductive molded body is formed by curing the polymer matrix component while maintaining the orientation of the fibrous thermally-conductive filler. The thermally-conductive molded body refers to the base material (molded body) for cutting out the sheet, which is the origin of the thermally-conductive sheet 1 that is cut to a predetermined size.

The size and shape of the hollow mold and the thermally-conductive molded body can be determined according to the size and shape of the required thermally-conductive sheet 1, and a cuboidal body having a cross-sectional length of 0.5 cm to 15 cm and a width of 0.5 cm to 15 cm is given as an example. The length of the cuboid can be determined, as necessary.

The method and conditions for curing the polymer matrix component can be changed according to the type of polymer matrix component. For example, when the polymer matrix component is a thermosetting resin, the curing temperature in thermal curing can be adjusted. Additionally, when the thermosetting resin contains a liquid silicone gel main agent and a curing agent, it is preferable for curing to be performed at a curing temperature of 80° C. to 120° C. The curing time in thermal curing is not particularly limited, but can be from 1 to 10 hours.

(Process B)

As illustrated in FIG. 2, in process B, in which the thermally-conductive molded body 6 is sliced into a sheet to form the molded body sheet 7, the thermally-conductive molded body 6 is cut into a sheet to be at an angle of 0° to 90°, more preferably 45° to 90°, with respect to the major axis direction of the oriented fibrous thermally-conductive filler. Thus, the fibrous thermally-conductive filler is oriented in the thickness direction of the sheet body 2.

The cutting of the thermally-conductive molded body 6 is performed using a slicing device. The slicing device is not particularly limited as long as it is means that can cut the thermally-conductive molded body 6, and any known slicing device can be appropriately used. For example, ultrasonic cutters, planes, and the like can be used.

The slicing thickness of the thermally-conductive molded body 6 is the thickness of the sheet body 2 of the thermally-conductive sheet 1 and can be appropriately set according to the use of the thermally-conductive sheet 1, for example, 0.5 to 3.0 mm.

Note that in process B, the molded body sheet 7 cut from the thermally-conductive molded body 6 may be subdivided into a plurality of molded body sheets 7 by being cut.

(Process C)

In process C, the first release film 3 is attached on one side of the molded body sheet 7, the second release film 4 is attached on another side of the molded body sheet 7, and press it. This press smoothens the surface of the molded body sheet 7 and bleeds the uncured component of the polymer matrix component to form the resin coating layer 5 between one side of the molded body sheet 7 and the first release film 3 and between the other side of the molded body sheet 7 and the second release film 4. Here, the sides 2a and 2b of the thermally-conductive sheet 1 are the sliced, then pressed, sides. Thus the thermally-conductive sheet 1 is formed, unevenness on the sheet surface is reduced, the exposed fibrous thermally-conductive filler is coated, adhesion to heat sources and heat dissipating members is improved, interfacial contact resistance under a light load is reduced, and heat transfer efficiency is improved.

Note that the pressing can be performed, for example, using a pair of pressing devices consisting of a flat plate and a press head having a flat surface. Pinch rolls may also be used to perform pressing.

The pressure when pressing is not particularly limited and can be appropriately selected according to the object thereof. However, when it is too low, the thermal resistance tends to not change compared to when pressing is not performed, and when it is too high, the sheet tends to stretch. Therefore, it is preferable to have a pressure range of 0.1 MPa to 100 MPa and more preferably a pressure range of 0.5 MPa to 95 MPa.

Plastic films such as PET films and polyethylene films can be used as the first release film 3 and the second release film 4, which are attached to both sides of the molded body sheet 7. In this case, the first release film 3 and the second release film 4 may be treated using a release treatment such as a wax treatment or a fluorine treatment on a side attached to the surface of the molded body sheet 7. Furthermore, the first release film 3 and the second release film 4 may be embossed.

Moreover, the first release film 3 and the second release film 4 are formed to have a different peel strength (N) from the sheet body 2 by making them have different thicknesses and/or materials. For example, in a 30 mm×30 mm thermally-conductive sheet 1, when a wax-treated PET film having a thickness of 25 μm is used as the first release film 3 and an embossed polyethylene film having a thickness of 80 μm is used as the second release film 4, after performing a 180-degree peel test in a tensile and compression testing machine with a load cell of 50 (N) and a velocity of 300 mm/min, the peel strength (N) from the sheet body 2 is 0.03 (N) for the first release film 3 (bending radius of 3 mm) and 0.05 (N) for the second release film 4 (bending radius of 0.5 mm or less).

(Process for Mounting Thermally-Conductive Sheet)

In actual use, the thermally-conductive sheet 1 is mounted on electronic components such as, for example, semiconductor devices or various heat-dissipating components such as heat sinks. At this time, the thermally-conductive sheet 1 is peeled off from the release film having the lower peel strength from the sheet body 2, for example, the first release film 3 in the example above. This allows one side 2a of the sheet body 2 to be exposed while being supported by the second release film 4, without the entirety of the sheet body 2 peeling off from the second release film 4 due to being adhered to the first release film 3. In the thermally-conductive sheet 1, one side 2a of the sheet body 2 having the resin coating layer 5 exposed is adhered to an electronic component such as a semiconductor device or a heat-dissipating component such as a heat sink, and then the second release film 4 is peeled off from the other side 2b of the sheet body 2.

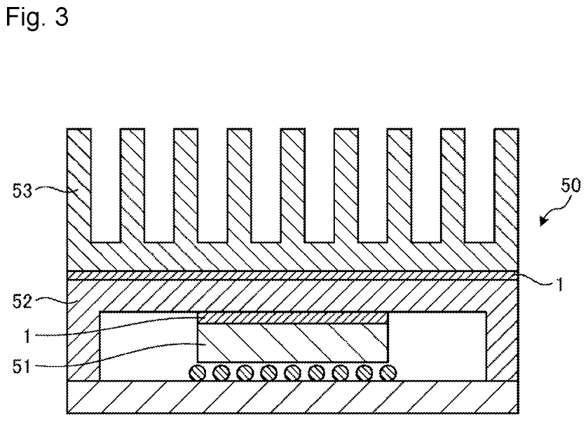

For example, as shown in FIG. 3, the thermally-conductive sheet 1 is mounted on a semiconductor device 50 built into various electronic devices and is interposed between a heat source and a heat-dissipating member. The semiconductor device 50 illustrated in FIG. 3 has at least an electronic component 51, a heat spreader 52, and the thermally-conductive sheet 1, and the thermally-conductive sheet 1 is interposed between the heat spreader 52 and the electronic component 51. Because the thermally-conductive sheet 1 is interposed between the heat spreader 52 and the heat sink 53, together with the heat spreader 52, it configures a heat-dissipating member that dissipates heat from the electronic component 51.

The electronic component 51 is not particularly limited and can be appropriately selected according to the object thereof, and examples include various semiconductor elements such as CPUs, MPUs, graphic computing elements, and image sensors, antenna elements, batteries, and the like. The heat spreader 52 is not particularly limited as long as it is a member for dissipating heat generated by the electronic component 51, and can be appropriately selected according to the object thereof. By using the thermally-conductive sheet 1, the semiconductor device 50 has high heat dissipation and also has an excellent electromagnetic wave suppression effect according to the content of magnetic powder in the sheet body 2.

Note that the mounting location of the thermally-conductive sheet 1 is not limited to being between the heat spreader 52 and the electronic component 51 or between the heat spreader 52 and the heat sink 53, and can naturally be appropriately selected according to the configuration of the electronic device or semiconductor device. In addition to the heat spreader 52 and the heat sink 53, heat-dissipating members can be anything that conducts and dissipates heat generated from a heat source to the exterior, such as radiators, coolers, die pads, printed circuit boards, cooling fans, Peltier elements, heat pipes, metal covers, and housings.

### Example 1

In the present Example, as shown in Table 1 below, first, silicone resin (an example of a binder): 34% by volume, scaled boron nitride (D50 is 40 μm) having a hexagonal crystal shape: 25% by volume, aluminum nitride (D50 is 1.5 μm): 19% by volume, spherical alumina particles (D50 is 5 μm): 19% by volume, zinc oxide (D50 is 1 μm): 1% by volume, aluminum hydroxide (D50 is 8 μm): 1% by volume, and a coupling agent: 1% by volume were uniformly mixed to prepare a resin composition for forming a thermally-conductive sheet.

Next, the resin composition for forming a thermally-conductive sheet was poured into a mold having a cuboidal-shaped interior space (opening: 50 mm×50 mm) using an extrusion molding method and heated in a 60° C. oven for 4 hours to form a molded block (the thermally-conductive molded body 6 illustrated in FIG. 2). Note that a release polyethylene terephthalate film was adhered to the inner surface of the mold so that the release treated side is inside. Next, as shown in Table 1, the obtained molded block was sliced into sheets using a carbide blade to obtain a thermally-conductive sheet 1 having scale-shaped boron nitride oriented in the sheet thickness direction. When doing so, as shown in Table 1, the molded block was sliced using a carbide blade to obtain an Sa of 3.442 μm and Sz of 40.990 μm on either side of the thermally-conductive sheet 1, and the thermally-conductive sheet 1 was obtained.

### Example 2

In the present Example, first, 100 g of pitch-based carbon fiber having an average fiber diameter of 9 μm and an average fiber length of 110 μm and 450 g of ethanol were put into a glass container and mixed with a stirring blade to obtain a slurry liquid. While nitrogen was added to the slurry liquid at a flow rate of 160 mL/min, making inert, 25 g of divinylbenzene (93% divinylbenzene) was added to the slurry. Ten minutes after the addition of divinylbenzene, 0.500 g of polymerization initiator (oil-soluble azo polymerization initiator), which had been previously dissolved in 50 g ethanol, was added to the slurry liquid. After stirring for five minutes after the addition, the inerting using nitrogen was stopped.

Thereafter, heating was started while stirring, a temperature of 70° C. was maintained, and the temperature was decreased to 40° C. Note that the reaction time was defined as the time from the start of heating to the start of temperature decrease. After the temperature was decreased, the slurry liquid was allowed to stand for 15 minutes to allow the solids dispersed in the slurry liquid to settle. After allowing to settle, the supernatant was removed by decantation, 750 g of solvent was added again and stirred for 15 minutes to wash the solids. After being washed, the solids were collected by suction filtration, and the collected solids were dried at 100° C. for six hours to obtain DVB insulation coated carbon fiber (an example of a carbon fiber whose surface is coated using an insulating material).

Next, in the present Example, as shown in Table 1, a silicone composition was prepared by mixing 28% by volume of silicone resin, 30% by volume of spherical alumina particles (D50 is 15 μm), 33% by volume of granular aluminum nitride (D50 is 1.5 μm), 1% by volume of aluminum hydroxide (D50 is 8 μm), 6% by volume of DVB insulation coated carbon fiber having an average fiber length of 110 μm, and 1% by volume of a coupling agent.

Next, the resin composition for forming a thermally-conductive sheet was poured into a mold having a cuboidal-shaped interior space (opening: 50 mm×50 mm) using an extrusion molding method and heated in a 100° C. oven for six hours to form a molded block. Note that a release polyethylene terephthalate film was adhered to the inner surface of the mold so that the release treated side is inside. Next, as shown in Table 1, the obtained molded block was sliced into the desired thickness using a carbide blade to obtain a thermally-conductive sheet 1 having carbon fiber oriented in the sheet thickness direction. When doing so, as shown in Table 1, the molded block was sliced using a carbide blade to obtain an Sa of 4.225 μm and Sz of 45.880 μm on either side of the thermally-conductive sheet 1, and the thermally-conductive sheet 1 was obtained.

### Example 3

In the present Example, first, 100 g of pitch-based carbon fiber having an average fiber diameter of 9 μm and an average fiber length of 110 μm, 200 g of tetraethoxysilane (TEOS), and 900 g of ethanol were put into a polyethylene container and mixed using a stirring blade. Thereafter, 176 g of reaction initiator (10% ammonia water) was added over 5 minutes while heating to 50° C. Stirring was performed for 3 hours, with the time at which the solvent was completely added at 0 min. After stirring was completed, cooling was performed, the solids were collected by suction filtration, the solids were washed using water and ethanol, and the solids were collected again by suction filtration. The collected solids were dried at 100° C. for two hours and further fired at 200° C. for eight hours to obtain SiO2 insulation coated carbon fiber (an example of carbon fiber whose surface is coated with an insulating material).

Next, in the present Example, a silicone composition was prepared by mixing 28% by volume of silicone resin, 30% by volume of spherical alumina particles (D50 is 15 μm), 1% by volume of spherical alumina particles (D50 is 5 μm), 1% by volume of aluminum hydroxide (D50 is 8 μm), 33% by volume of granular aluminum nitride (D50 is 1.5 μm), 6% by volume of SiO2 insulation coated carbon fiber having an average fiber length of 110 μm, and 1% by volume of a coupling agent.

Next, the resin composition for forming a thermally-conductive sheet was poured into a mold having a cuboidal-shaped interior space (opening: 50 mm×50 mm) using an extrusion molding method and heated in a 100° C. oven for six hours to form a molded block. Here, a release polyethylene terephthalate film was adhered to the inner surface of the mold so that the release treated side is inside. Next, as shown in Table 1, the obtained molded block was sliced into the desired thickness using a carbide blade to obtain a thermally-conductive sheet 1 having carbon fiber oriented in the sheet thickness direction. When doing so, as shown in Table 1, the molded block was sliced using a carbide blade to obtain an Sa of 3.982 μm and Sz of 49.784 μm on either side of the thermally-conductive sheet 1, and the thermally-conductive sheet 1 was obtained.

### Example 4

In the present Example, as shown in Table 1 below, a silicone composition was prepared by mixing 28% by volume of silicone resin, 6% by weight of carbon fiber, 30% by volume of spherical alumina particles (D50 is 15 μm), 1% by volume of spherical alumina particles (D50 is 5 μm), 33% by volume of granular aluminum nitride (D50 is 1.5 μm), 1% by volume of aluminum hydroxide (D50 is 8 μm), and 1% by volume of a coupling agent.

Next, the resin composition for forming a thermally-conductive sheet was poured into a mold having a cuboidal-shaped interior space (opening: 50 mm×50 mm) using an extrusion molding method and heated in a 100° C. oven for six hours to form a molded block. Note that a release polyethylene terephthalate film was adhered to the inner surface of the mold so that the release treated side is inside. Next, as shown in Table 1, the obtained molded block was sliced into the desired thickness using a carbide blade to obtain a thermally-conductive sheet 1 having carbon fiber oriented in the sheet thickness direction. When doing so, as shown in Table 1, the molded block was sliced using a carbide blade to obtain an Sa of 4.989 μm and Sz of 46.879 μm on either side of the thermally-conductive sheet 1, and the thermally-conductive sheet 1 was obtained.

### Comparative Examples 1 to 4

In Comparative Examples 1 to 4, the molded block obtained in Examples 1 to 4 was sliced using a cutter knife (alloy tool steel) to obtain a thermally-conductive sheet 1 having carbon fiber oriented in the thickness direction. When doing so, in Comparative Example 1, as shown in Table 1, the molded block was sliced using a carbide blade to obtain an Sa of 5.687 μm and Sz of 71.652 μm on either side of the thermally-conductive sheet 1, and the thermally-conductive sheet 1 was obtained. Furthermore, in Comparative Example 2, as shown in Table 1, the molded block was sliced using a carbide blade to obtain an Sa of 5.899 μm and Sz of 65.050 μm on either side of the thermally-conductive sheet 1, and the thermally-conductive sheet 1 was obtained. Furthermore, in Comparative Example 3, as shown in Table 1, the molded block was sliced using a carbide blade to obtain an Sa of 5.680 μm and Sz of 57.380 μm on either side of the thermally-conductive sheet 1, and the thermally-conductive sheet 1 was obtained. Moreover, in Comparative Example 4, as shown in Table 1, the molded block was sliced using a carbide blade to obtain an Sa of 7.761 μm and Sz of 65.230 μm on either side of the thermally-conductive sheet 1, and the thermally-conductive sheet 1 was obtained.

(Evaluation of Thermal Properties)

The thermal resistance of the thermally-conductive sheet 1 obtained in each of Examples 1 to 4 and Comparative Examples 1 to 4 was measured using the following procedure. The thermally-conductive sheet 1 having the above thickness was processed to a circular shape with a diameter of 20 mm to obtain a test piece. Next, the obtained test piece was interposed between coppers and a thermal resistance [° C.×cm2/W] was measured at a load of 1 kgf/cm2. The thickness at the time of measurement was plotted on the horizontal axis and the thermal resistance was plotted on the vertical axis, and the contact thermal resistance was obtained from the intercept.

(Surface Roughness)

The surface roughness of the thermally-conductive sheet 1 obtained in each of Examples 1 to 4 and comparative examples 1 to 4 was measured using a one-shot 3D shape machine VR5200 manufactured by Keyence Corporation. Sa (arithmetical mean height) is a parameter that extends Ra (arithmetical mean height of the line) to surfaces and represents the average of the absolute difference in height of each point with respect to the average face of the surface. Sa is commonly used to evaluate surface roughness. Sz (maximum height) represents the distance from the highest point to the lowest point on the surface. As shown in Table 1, when comparing Example 1 with Comparative Example 1, Example 2 with Comparative Example 2, Example 3 with Comparative Example 3, and Example 4 with Comparative Example 4, the thermal conductivity and dielectric breakdown voltage of the thermally-conductive sheet 1 of the Examples are higher than those of the thermally-conductive sheet 1 of the Comparative Examples. This shows that by making Sa 5 μm or less, Sz 50 μm or less, and the dielectric breakdown voltage 0.5 kV/mm or greater for a thermally-conductive sheet 1 containing a binder and an anisotropic thermally-conductive filler and in which the anisotropic thermally-conductive filler is oriented in the thickness direction, a thermally-conductive sheet 1 can be obtained having low thermal resistance while still having insulating properties. That is, even when an insulating material is used, a thermally-conductive sheet 1 can be obtained that can favorably transfer heat in the thickness direction by setting Sa and Sz to a predetermined value or less. In an electronic device, by interposing the thermally-conductive sheet 1 of Examples 1 to 4 between an electronic component 51 (an example of a heating element) and a heat-dissipating fan, heat-dissipating plate, or the like (an example of a heat-dissipating member), the heat conductivity to the heat-dissipating member can be improved and heat can be efficiently dissipated.

TABLE 1

| | | | | | Comp. | Comp. | Comp. | Comp. |
|---|---|---|---|---|---|---|---|---|
| | Ex. 1 | Ex. 2 | Ex. 3 | Ex. 4 | Ex. 1 | Ex. 1 | Ex. 1 | Ex. 1 |
| Silicone | 34 | 28 | 28 | 28 | 34 | 28 | 28 | 28 |
| Carbon Fiber | — | — | — | 6 | — | — | — | 6 |
| Alumina 15 μm | — | 30 | 30 | 30 | — | 30 | 30 | 30 |
| Alumina 5 μm | 19 | 1 | 1 | 1 | 19 | 1 | 1 | 1 |
| Aluminum | 19 | 33 | 33 | 33 | 19 | 33 | 33 | 33 |
| nitride 1.5 μm | | | | | | | | |
| Zinc oxide 1 μm | 1 | — | — | — | 1 | — | — | — |
| Aluminum | 1 | 1 | 1 | 1 | 1 | 1 | 1 | 1 |
| hydroxide | | | | | | | | |
| (crumbling) 8 μm | | | | | | | | |
| Boron nitride | 25 | — | — | — | 25 | — | — | — |
| (scale-shaped) | | | | | | | | |
| 40 μm | | | | | | | | |
| Coupling agent | 1 | 1 | 1 | 1 | 1 | 1 | 1 | 1 |
| SiO2 coated | — | — | 6 | — | — | — | 6 | — |
| carbon fiber | | | | | | | | |
| DVB coated | — | 6 | — | — | — | 6 | — | — |
| carbon fiber | | | | | | | | |
| Orientation of | Thickness | Thickness | Thickness | Thickness | Thickness | Thickness | Thickness | Thickness |
| fiber/scale- | Direction | Direction | Direction | Direction | Direction | Direction | Direction | Direction |
| shaped filler | | | | | | | | |
| Thickness [mm] | 0.15 | 1 | 1 | 1 | 0.15 | 1 | 1 | 1 |
| Sa [μm] | 3.442 | 4.225 | 3.982 | 4.989 | 5.687 | 5.899 | 5.680 | 7.761 |
| Sz [μm] | 40.990 | 45.880 | 49.784 | 46.879 | 71.652 | 65.050 | 57.380 | 65.230 |
| Thermal | 2.02 | 8.11 | 8.01 | 9.58 | 1.72 | 7.32 | 7.15 | 8.33 |
| conductivity | | | | | | | | |
| at 10% | | | | | | | | |
| compression | | | | | | | | |
| [W/mK] | | | | | | | | |
| Dielectric | 3.28 | 1.44 | 0.90 | 0.50 | 3.10 | 1.28 | 0.87 | 0.49 |
| breakdown | | | | | | | | |
| voltage at | | | | | | | | |
| 1 mm [kV] | | | | | | | | |

Ex. = Example, Comp. Ex. = Comparative Example

### REFERENCE SIGNS LIST

1 Thermally-conductive sheet, 2 Sheet body, 2a Side, 2b Side, 3 First release film, 4 Second release film, 5 Resin coating layer, 6 Thermally-conductive molded body, 7 Molded body sheet, 50 Semiconductor device, 51 Electronic component, 52 Heat spreader, 53 Heat sink

1. A thermally-conductive sheet comprising: a binder; and an anisotropic thermally-conductive filler,
wherein the anisotropic thermally-conductive filler is oriented in a thickness direction of the thermally-conductive sheet, and
an arithmetical mean height Sa is 5 μm or less and a maximum height Sz is 50 μm or less on either surface of the thermally-conductive sheet, and
a dielectric breakdown voltage of the thermally-conductive sheet is 0.5 kV/mm or higher.

2. The thermally-conductive sheet according to claim 1, wherein the anisotropic thermally-conductive filler comprises at least one of boron nitride, a carbon fiber, and a carbon fiber having an insulating material layer on a surface thereof.

3. The thermally-conductive sheet according to claim 1, further comprising at least one of alumina, aluminum nitride, zinc oxide, and aluminum hydroxide.

4. The thermally-conductive sheet according to claim 1, wherein the binder comprises silicone.

5. An electronic device, comprising:
the thermally-conductive sheet according to claim 1;
a heating element; and
a heat-dissipating member,
wherein the thermally-conductive sheet is interposed between the heating element and the heat-dissipating member.

6. The thermally-conductive sheet according to claim 2, further comprising at least one of alumina, aluminum nitride, zinc oxide, and aluminum hydroxide.

7. The thermally-conductive sheet according to claim 2, wherein the binder comprises silicone.

8. The thermally-conductive sheet according to claim 3, wherein the binder comprises silicone.

9. The thermally-conductive sheet according to claim 6, wherein the binder comprises silicone.
